(19) United States
(12) Patent Application Publication
(10) Pub. No.: US 2026/0086303 A1
(43) Pub. Date: Mar. 26, 2026

(54) SEMICONDUCTOR PACKAGE AND METHOD FOR MANUFACTURING THE SAME

(71) Applicant: Samsung Electronics Co., Ltd., Suwon-si (KR)

(72) Inventor: Junghoon KANG, Suwon-si (KR)

(73) Assignee: Samsung Electronics Co., Ltd., Suwon-si (KR)

(21) Appl. No.: 19/091,988

(22) Filed: Mar. 27, 2025

(30) Foreign Application Priority Data
Sep. 25, 2024 (KR) 10-2024-0129778

(51) Int. Cl. G02B 6/42; H01L 23/13; H01L 23/15; H01L 23/48; H01L 23/538; H01L 25/00; H01L 25/16

(52) U.S. Cl. CPC G02B 6/4243; G02B 6/4239; H10W 20/20; H10W 70/68; H10W 90/00; H10W 70/60; H10W 70/611; H10W 70/692

(57) ABSTRACT

A semiconductor package including an interposer including a glass core and a substrate around the glass core, the substrate including a recess portion on a side surface thereof, a photonic integrated circuit (PIC) on the interposer, and an optical connector next to the interposer may be provided. The optical connector may include a connector portion including a plurality of optical fibers connected to the photonic integrated circuit, a coupling portion inserted into the recess portion, and a main body portion connecting the connector portion to the coupling portion.

### CROSS-REFERENCE TO RELATED APPLICATION

This application claims priority to and the benefit of Korean Patent Application No. 10-2024-0129778 filed at the Korean Intellectual Property Office on Sep. 25, 2024, the entire contents of which are incorporated herein by reference.

### BACKGROUND

### (a) Field

The present disclosure relates to semiconductor packages and/or methods for manufacturing the same.

### (b) Description of the Related Art

As demand for data used in an individual electronic device increases, traffic of a data center is increasing. Thus, a co-packaged optics (CPO) that is a device for processing a high-bandwidth signal transmitted and received in the data center and includes an optical engine and an integrated circuit, has been developed and used.

The co-packaged optics (CPO) includes the optical engine processing an optical signal transferred via an optical fiber from the data center. The optical fiber carrying the optical signal from outside may be optically coupled to a grating coupler within the optical engine, and the optical signal may move within the optical engine through the grating coupler. A method of transferring the optical signal using the grating coupler has an advantage of being easy to manufacture a package, but because transmission or reflection of a wavelength is determined by a width of a grating, the method of transferring the optical signal using the grating coupler is difficult to implement wavelength division multiplexing (WDM) and high bandwidth-based high-speed communication becomes challenging or impossible.

There is a method of transferring the optical signal using an edge coupler that is different from the method of transferring the optical signal using the grating coupler. The optical fiber carrying the optical signal from outside may be optically coupled to the edge coupler, and the optical signal may move within the optical engine through the edge coupler. A grating is not used if the method of transferring the optical signal using the edge coupler is used, so that the method of transferring the optical signal using the edge coupler has an advantage of being capable of transferring the optical signal regardless of a wavelength and implementing wavelength division multiplexing (WDM) and high bandwidth-based high-speed communication. However, the method of transferring the optical signal using the edge coupler has a disadvantage of increasing an insertion loss if the optical fiber and the edge coupler are misaligned.

Therefore, it is desired to develop a new package technology that may solve the above-described problems of the co-packaged optics (CPO).

### SUMMARY

In a semiconductor package to which a method of transferring an optical signal using an edge coupler is applied, an interposer and an optical connector configured to accurately align an optical fiber to the edge coupler may be provided.

A semiconductor package according to an example embodiment includes an interposer including a glass core and a substrate around the glass core, the substrate including a recess portion on a side surface thereof, a photonic integrated circuit (PIC) on the interposer, and an optical connector next to the interposer. The optical connector includes a connector portion including a plurality of optical fibers connected to the photonic integrated circuit, a coupling portion inserted into the recess portion, and a main body portion connecting the connector portion to the coupling portion.

A semiconductor package according to an example embodiment includes an interposer including a first redistribution structure, a glass core on the first redistribution structure, a substrate on the first redistribution structure and around the glass core, a molding material on the first redistribution structure and between the glass core and the substrate, and a second redistribution structure on the glass core and the substrate, the substrate including a plurality of recess portions on a side surface thereof, a logic die on the interposer, a plurality of memory dies on the interposer; a plurality of optical engines on the interposer, and a plurality of optical connectors next to the interposer. Each of the plurality of optical connectors includes a connector portion including an optical fiber array connected to a corresponding optical engine among the plurality of optical engines, a coupling portion inserted into a corresponding recess portion among the plurality of recess portions, and a main body portion connecting the connector portion to the coupling portion.

A method for manufacturing a semiconductor package according to an example embodiment includes manufacturing an interposer including a glass core and a substrate around the glass core, forming a recess portion on a side surface of the substrate, mounting a photonic integrated circuit (PIC) on the interposer, and coupling an optical connector to the photonic integrated circuit and the recess portion. The optical connector includes, a connector portion including a plurality of optical fibers connected to the photonic integrated circuit, a coupling portion inserted into the recess portion, and a main body portion connecting the connector portion to the coupling portion.

An optical fiber may be precisely aligned to an edge coupler, so that an insertion loss of an optical signal is reduced.

An optical connector may function as a heat dissipation structure that dissipates heat generated within a co-packaged optics (CPO) to the outside, and may improve a heat dissipation characteristic of the co-packaged optics (CPO).

An interposer may include a substrate at an edge thereof, and the substrate may improve stiffness of the co-packaged optics (CPO).

The substrate itself may have a routing path, and in addition, a redistribution pattern may be formed on upper and lower portions of the substrate so that signal and electric power routing paths through the substrate and the redistribution pattern on the substrate are added.

### BRIEF DESCRIPTION OF THE DRAWINGS

FIG. 1 is a plan view showing a semiconductor package of an example embodiment.

FIG. 2 is a cross-sectional view showing the semiconductor package of an example embodiment.

FIG. 3 is a cross-sectional view showing the semiconductor package of an example embodiment.

FIG. 4 is a cross-sectional view showing the semiconductor package of an example embodiment.

FIG. 5 is a perspective view showing the semiconductor package of an example embodiment.

FIG. 6 is a perspective view showing an optical fiber array of an example embodiment.

FIGS. 7A and 7B are cross-sectional views showing grooves of some example embodiments.

FIG. 8 is a cross-sectional view showing a semiconductor package of an example embodiment.

FIG. 9 is a cross-sectional view showing a semiconductor package of an example embodiment.

FIGS. 10 to 14 are cross-sectional views showing a method for manufacturing a glass core of an example embodiment.

FIGS. 15 to 28 are cross-sectional views showing a method for manufacturing the semiconductor package of an example embodiment.

### DETAILED DESCRIPTION

Some example embodiments of the present disclosure will be described more fully hereinafter with reference to the accompanying drawings so that those skilled in the art could easily implement the example embodiments. The present disclosure may be modified in various ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

In the drawings, a size and a thickness of each element are arbitrarily illustrated for ease of description, and example embodiments are not necessarily limited to those illustrated in the drawings.

Throughout the specification, when a part is “connected” to another part, it includes not only a case where the part is “directly connected” but also a case where the part is “indirectly connected” with another part in between. Unless explicitly stated to the contrary, the word “comprise” and variations such as “comprises” and “comprising” should be understood to imply the inclusion of stated elements but not the exclusion of any other elements.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” means disposed on or below a referenced part, and does not necessarily mean disposed on the upper side of the referenced part based on a gravitational direction.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Hereinafter, semiconductor packages of some example embodiments and methods for manufacturing the same will be described with reference to the drawings.

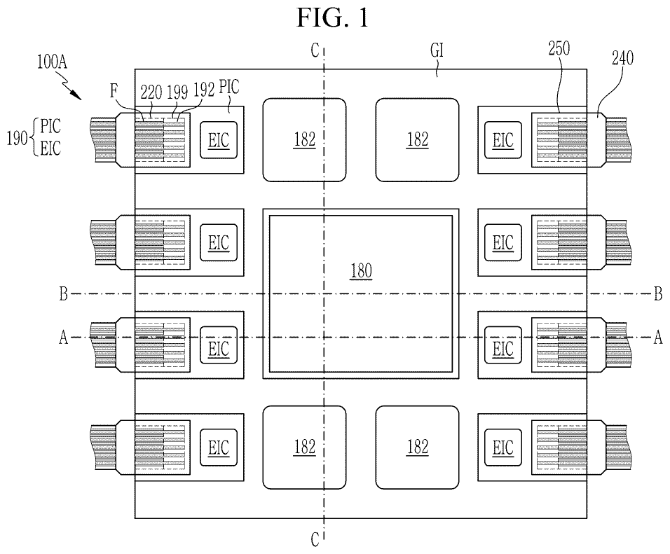

FIG. 1 is a plan view showing the semiconductor package 100A of an example embodiment.

Referring to FIG. 1, the semiconductor package 100A may include an interposer GI, a logic die 180, a memory die 182, and an optical engine 190. The semiconductor package 100A may be a co-packaged optics (CPO).

The interposer GI may electrically connect the logic die 180, the memory die 182, and the optical engine 190. The interposer GI may reduce a routing distance between the logic die 180, the memory die 182, and/or the optical engine 190, or a routing distance between an external device and the logic die 180, a routing distance between the external device and the memory die 182, and a routing distance between the external device and the optical engine 190, may enable high-speed transmission of signals, may reduce a noise, and/or may reduce power consumption. The interposer GI may be a glass interposer or a composite interposer. The interposer GI may include electronic elements such as active or passive elements therein.

The logic die 180, the memory die 182, and the optical engine 190 may be disposed above the interposer GI. The logic die 180, the memory die 182, and the optical engine 190 may be electrically connected through the interposer GI, and may communicate with each other. The number of each of logic dies 180, memory dies 182, and optical engines 190 is not limited to the number shown in FIG. 1, and more or fewer logic dies 180, more or fewer memory dies 182, and more or fewer optical engines 190 may be included within the scope of the present disclosure. Additionally, the logic die 180, the memory die 182, and the optical engine 190 may have an arrangement, a disposition, a shape, or a configuration different from that shown in FIG. 1.

The logic die 180 may be centrally disposed on the interposer GI. The logic die 180 may be disposed between the optical engines 190 and between the memory dies 182. The logic die 180 may process an electrical signal transferred from an electronic integrated circuit EIC through the interposer GI. Additionally, the logic die 180 may generate an electrical signal for controlling the electronic integrated circuit EIC, and may transmit the generated electrical signal to the electronic integrated circuit EIC. The memory die 182 may be provided in a plural number, and the plurality of memory dies 182 may be disposed around the logic die 180, or on both sides of the logic die 180.

The optical engine 190 may be provided in a plural number, and the plurality of optical engines 190 may be disposed around the logic die 180, or on both sides of the logic die 180. The optical engine 190 may include a photonic integrated circuit PIC and the electronic integrated circuit EIC on the photonic integrated circuit PIC. The optical engine 190 may be connected to optical fibers F within a connector portion 220 via an edge coupler 199. The optical fibers F may be edge-mounted to the photonic integrated circuit PIC. The edge coupler 199 may include first optical waveguides 192, and each first optical waveguide of the first optical waveguides 192 may be connected in a line to a corresponding optical fiber F of the optical fibers F. Due to the connection, the semiconductor package 100A may perform optical communication between the logic die 180 and an external data center.

The photonic integrated circuit PIC may convert an optical signal received from the optical fiber F into an electrical signal, and may transmit the electrical signal to the electronic integrated circuit EIC. Additionally, the photonic integrated circuit PIC may transmit an optical signal based on an electrical signal received from the electronic integrated circuit EIC to the optical fiber F.

The electronic integrated circuit EIC may receive, amplify, and transmit a corresponding electrical signal generated based on the optical signal received from the optical fiber F to the logic die 180. Additionally, the electronic integrated circuit EIC may communicate with the photonic integrated circuit PIC based on an electrical signal from the logic die 180.

In this way, the optical engine 190 may provide high-speed optical communication with the external data center.

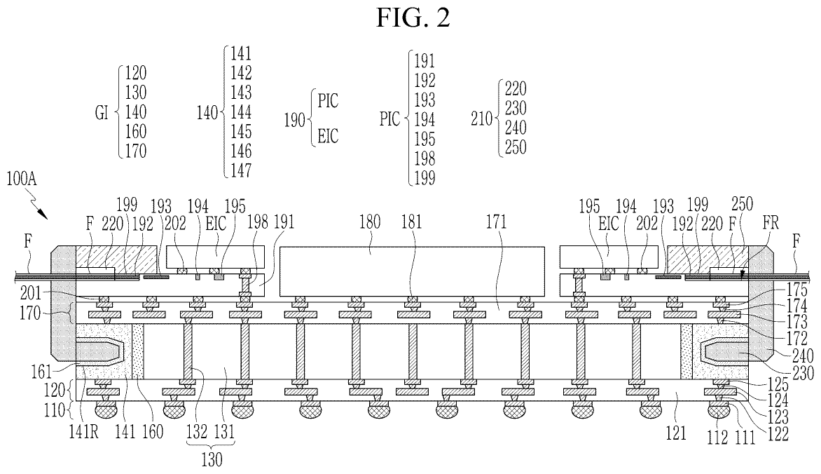

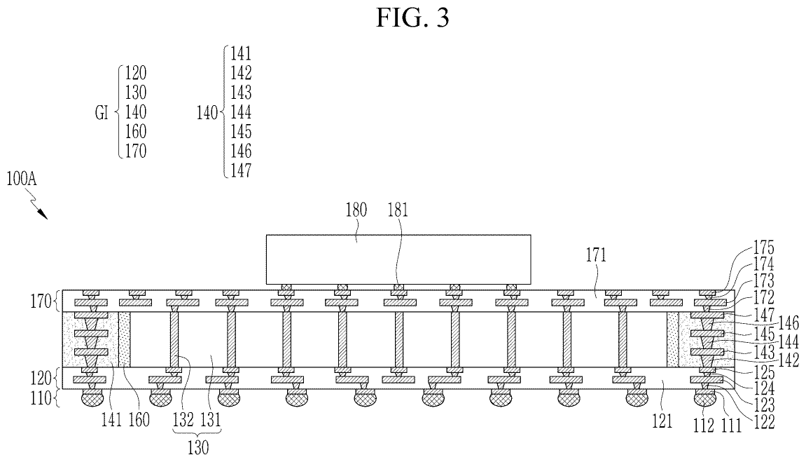

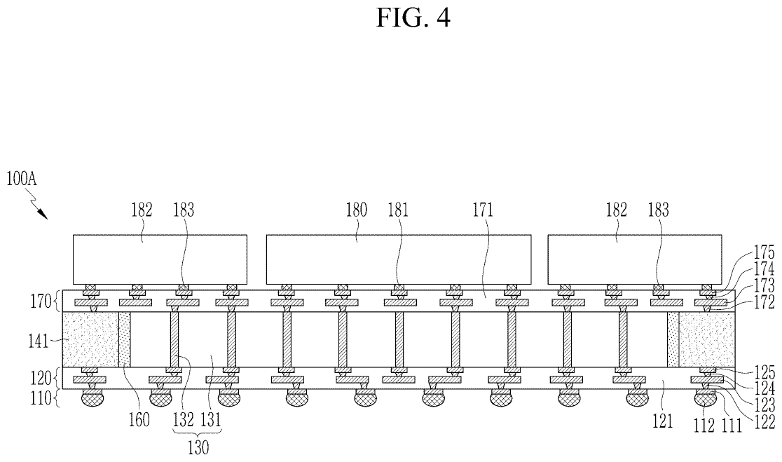

FIG. 2 is a cross-sectional view of the semiconductor package 100A of FIG. 1 cut along a line A-A. FIG. 3 is a cross-sectional view of the semiconductor package 100A of FIG. 1 cut along a line B-B. FIG. 4 is a cross-sectional view of the semiconductor package 100A of FIG. 1 cut along a line C-C.

Referring to FIG. 2, FIG. 3, and FIG. 4, the semiconductor package 100A may include an external connection structure 110, the interposer GI, the logic die 180, the memory die 182, and the optical engine 190. The semiconductor package 100A may be manufactured based on a fan-out wafer level package (FOWLP) technology or a fan-out panel level package (FOPLP) technology.

The external connection structure 110 may be disposed on a lower surface of the interposer GI. The external connection structure 110 may include bump structures. The bump structure may include a pillar 111 and a solder 112. The bump structure may electrically connect the interposer GI to an external device.

The interposer GI may include a first redistribution structure (or a lower redistribution structure) 120, a glass core 130, a substrate 140, a molding material 160, and a second redistribution structure (or an upper redistribution structure) 170. The interposer GI may include a glass interposer, but example embodiments are not limited thereto, and the interposer GI may include a silicon interposer, an organic interposer, or an interposer including a silicon bridge therein.

The first redistribution structure 120 may include a first dielectric 121, first redistribution vias 122, first redistribution lines 123, second redistribution vias 124, and second redistribution lines 125. In an example embodiment, the first redistribution structure 120 including fewer or more redistribution lines and fewer or more redistribution vias may be included in the scope of the present disclosure.

The first dielectric 121 may protect and insulate the first redistribution vias 122, the first redistribution lines 123, the second redistribution vias 124, and the second redistribution lines 125. The glass core 130, the substrate 140, and the molding material 160 may be disposed on an upper surface of the first dielectric 121. The external connection structure 110 may be disposed on a lower surface of the first dielectric 121. The first redistribution vias 122, the first redistribution lines 123, the second redistribution vias 124, and the second redistribution lines 125 may be sequentially disposed from below within the first dielectric 121, and may be electrically connected to each other.

The glass core 130 may be disposed on the first redistribution structure 120. The glass core 130 may include a core base 131 and through glass vias (TGVs) 132. In an example embodiment, the core base 131 may include borosilicate glass, quartz, or non-alkali glass. Like a silicon material, the glass material may be formed so that a surface roughness thereof is about 10 nm or less. Therefore, it is possible to form the through glass vias (TGVs) 132 having an ultra-fine pitch within the core base 131 of the glass material.

The through glass vias (TGVs) 132 may be disposed through the core base 131. Each of the through glass vias (TGVs) 132 may be disposed between the first redistribution structure 120 and the second redistribution structure 170, and may electrically connect the second redistribution structure 170 to the first redistribution structure 120. In an example embodiment, each of the through glass vias (TGVs) 132 may have a width in a horizontal direction ranging from about 0.01 μm to about 30 μm. In an example embodiment, adjacent through glass vias (TGVs) among the through glass vias (TGVs) 132 may be disposed with an interval in a horizontal direction ranging from about 1 μm to about 30 μm.

The substrate 140 may be disposed on the first redistribution structure 120. The substrate 140 may be disposed next to the glass core 130. The substrate 140 may surround the glass core 130. In an example embodiment, the substrate 140 may include a printed circuit board (PCB). In an example embodiment, the substrate 140 may include a copper clad laminate (CCL) in which an insulating layer and a conductive layer are alternately laminated. In an example embodiment, the substrate 140 may include an embedded trace substrate (ETS) without a core. The substrate 140 may include a recess portion 141R capable of accommodating a coupling portion 230 of an optical connector 210. The recess portion 141R may have a shape recessed from a side surface of the substrate 140. The recess portion 141R may have a shape conformal to or corresponding to a shape of the coupling portion 230 of the optical connector 210. The number of recess portions 141R formed in the substrate 140 may be equal to the number of optical engines 190 and the number of optical connectors 210. The substrate 140 may reinforce stiffness of the interposer GI, and stiffness of the co-packaged optics (CPO) may be improved by the substrate 140 included in the interposer GI.

Referring to FIG. 3, the substrate 140 may include a substrate base 141, a first via 142, a first wiring layer 143, a second via 144, a second wiring layer 145, a third via 146, and a third wiring layer 147. The first via 142, the first wiring layer 143, the second via 144, the second wiring layer 145, the third via 146, and the third wiring layer 147 may be sequentially disposed from below within the substrate base 141, and may be electrically connected to each other. The substrate 140 may include a signal routing path and an electric power routing path separate from the glass core 130. In some example embodiments, the substrate 140 may include fewer or more vias and fewer or more wiring layers.

Referring back to FIGS. 2, 3, and 4, the molding material 160 may be disposed between the glass core 130 and the substrate 140 on the first redistribution structure 120, and may cover the glass core 130 and the substrate 140.

The second redistribution structure 170 may include a second dielectric 171, third redistribution vias 172, third redistribution lines 173, fourth redistribution vias 174, and fourth redistribution lines 175. In some example embodiments, the second redistribution structure 170 may include fewer or more redistribution lines and fewer or more redistribution vias.

The second dielectric 171 may protect and insulate the third redistribution vias 172, the third redistribution lines 173, the fourth redistribution vias 174, and the fourth redistribution lines 175. The logic die 180, the memory dies 182 of FIG. 4, and the optical engine 190 may be disposed above an upper surface of the second dielectric 171. The glass core 130, the substrate 140, and the molding material 160 may be disposed on a lower surface of the second dielectric 171. The third redistribution vias 172, the third redistribution lines 173, the fourth redistribution vias 174, and the fourth redistribution lines 175 may be sequentially disposed from below within the second dielectric 171, and may be electrically connected to each other.

According to the above example embodiment of the present disclosure, because the substrate 140 includes the via and the wiring layer, the substrate 140 itself may have a routing path. In addition, because the first redistribution structure 120 is formed at a lower portion of the substrate 140 and the second redistribution structure 170 is formed at an upper portion of the substrate 140, it is possible to additionally form signal and electric power routing paths disposed through a wiring pattern within the substrate 140 and redistribution patterns on the upper and lower portions of the substrate 140 within the semiconductor package 100A. Therefore, it is possible to secure a spatial margin for designing various signal and electric power routing paths.

The logic die 180 may be disposed above the interposer GI. The logic die 180 may be electrically connected to the interposer GI by connection members 181. In an example embodiment, the logic die 180 may include a system on chip (SoC), a central processing unit (CPU), a graphics processing unit (GPU), an application processor (AP), or an application specific integrated circuit (ASIC).

Referring to FIG. 4, the memory die 182 may be disposed above the interposer GI. The memory die 182 may be disposed next to the logic die 180. In an example embodiment, the memory die 182 may include a dynamic random access memory (DRAM), a static random access memory (SRAM), or a high bandwidth memory (HBM).

Referring back to FIG. 2, the optical engine 190 may be disposed above the interposer GI. The optical engine may be disposed next to the logic die 180 and the memory die 182. The optical engine 190 may include the photonic integrated circuit PIC and the electronic integrated circuit EIC.

The photonic integrated circuit PIC may include a die base 191, first optical waveguides 192, second optical waveguides 193, a photo detector 194, a modulator 195, through silicon vias 198, and the edge coupler 199. The die base 191 may include optical devices or integrated circuit devices capable of generating, detecting, and transmitting an optical signal and converting between the optical signal and an electrical signal. The first optical waveguides 192, the second optical waveguides 193, the photo detector 194, the modulator 195, the through silicon vias 198, and the edge coupler 199 may be included within the die base 191.

The optical signal from the outside may move within the connector portion 220 of the optical connector 210, and may be emitted from the connector portion 220 to be incident on the edge coupler 199 connected to the connector portion 220.

The optical signal incident on the edge coupler 199 may move within the edge coupler 199, and may be emitted from the edge coupler 199 toward the second optical waveguides 193. The optical signal emitted from the edge coupler 199 may be incident on the second optical waveguides 193.

The second optical waveguides 193 may move the optical signal emitted from the edge coupler 199. The second optical waveguides 193 may be optically coupled to the edge coupler 199. In an example embodiment, the second optical waveguides 193 may include silicon or silicon nitride. The optical signal emitted from the second optical waveguides 193 may be incident on the photo detector 194.

The photo detector 194 may be optically coupled to the second optical waveguides 193, and may detect an optical signal from the second optical waveguides 193. The photo detector 194 may convert the detected optical signal into an electrical signal. The photo detector 194 may be electrically coupled to the electronic integrated circuit EIC. The photo detector 194 may include an active area. In an example embodiment, the photo detector 194 may include silicon or germanium.

The modulator 195 may be electrically coupled to the electronic integrated circuit EIC, and may modulate an electrical signal from the electronic integrated circuit EIC into an optical signal. The modulator 195 may be optically coupled to the second optical waveguides 193. The optical signal generated in the modulator 195 may be sequentially transferred to the connector portion 220 of the optical connector 210 through the second optical waveguides 193 and the edge coupler 199, and may be moved to the external data center.

The through silicon vias 198 may be disposed between the interposer GI and the electronic integrated circuit EIC, and may electrically connect the electronic integrated circuit EIC to the interposer GI. The photonic integrated circuit PIC may include vias and wirings for routing an electrical signal.

The edge coupler 199 may be disposed within the die base 191. The edge coupler 199 may include the first optical waveguides 192. The first optical waveguides 192 may be uniformly disposed. The edge coupler 199 may be optically coupled to the connector portion 220 of the optical connector 210. Each of the first optical waveguides 192 may be connected in a line and optically to a corresponding optical fiber F among the optical fibers F of the connector portion 220 of the optical connector 210. The edge coupler 199 may be optically coupled to an optical device (e.g., a photonic device) of the photonic integrated circuit PIC. The edge coupler 199 may be configured to direct the optical signal toward the second optical waveguides 193. In an example embodiment, the edge coupler 199 may include silicon or silicon nitride. The edge coupler 199 may be configured to be independent of a wavelength and reduce or prevent the optical signal from being lost, and the edge coupler 199 may have a material, a shape, or an orientation for this.

The electronic integrated circuit EIC may be disposed above the photonic integrated circuit PIC. A plurality of electronic integrated circuits EIC may be disposed above the photonic integrated circuit PIC. The electronic integrated circuit EIC may receive, amplify, and transmit an electrical signal, and may communicate with the logic die 180 and the photonic integrated circuit PIC. The electronic integrated circuit EIC may communicate with the logic die 180 through the through silicon vias 198 and the interposer GI. The electronic integrated circuit EIC may communicate with the photonic integrated circuit PIC via connection members 202. The electronic integrated circuit EIC may control an operation of the photonic integrated circuit PIC, or may process an electrical signal received from the photonic integrated circuit PIC. The electronic integrated circuit EIC may be electrically coupled to the photo detector 194 and the modulator 195, and may be configured to control the photo detector 194 and the modulator 195. In an example embodiment, the electronic integrated circuit EIC may include at least one of a central processing unit (CPU), a serial converter/deserial converter (SerDes), a controller, a driver, or an amplifier.

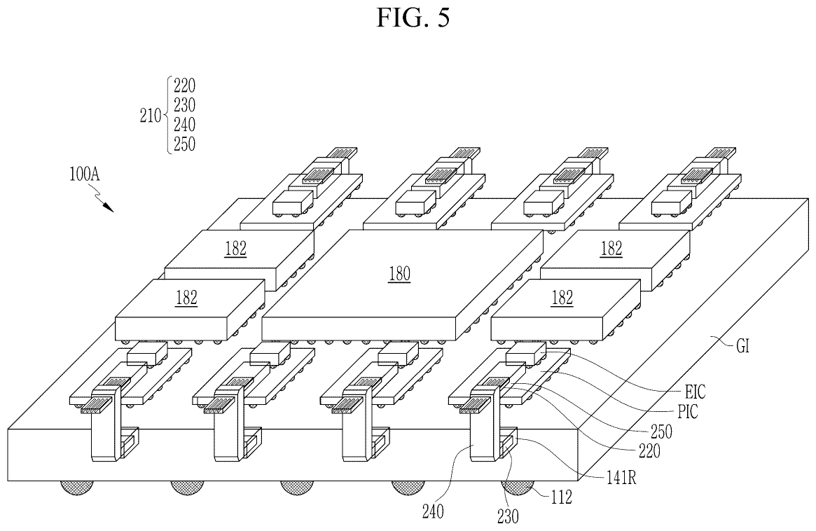

A disposition, an arrangement, and coupling of the optical connectors 210 may be referred to FIG. 5. FIG. 5 is a perspective view showing the semiconductor package 100A of an example embodiment. Referring to FIG. 1, FIG. 2, and FIG. 5, the optical connectors 210 may be disposed next to the interposer GI. The optical connectors 210 may be disposed to contact a side surface of the interposer GI, a side surface of the optical engine 190, and an upper surface of the optical engine 190. The optical connectors 210 may be coupled to the interposer GI and the optical engine 190. The number of the optical connectors 210 may match the number of the optical engines 190. The number, an arrangement, a position, a shape, and a structure of the optical connectors 210, coupling of the optical connector 210 and the optical engine 190, and coupling of the optical connector 210 and the interposer GI are not limited to that shown in FIG. 5. According to example embodiments, the number, the arrangement, the position, the shape, the structure, and/or the coupling of the optical connector 210 may vary.

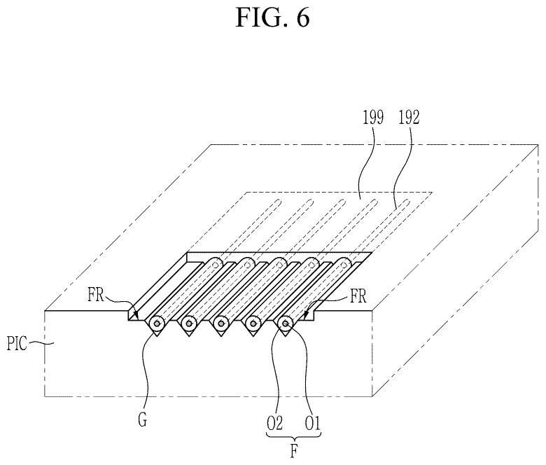

Each optical connector 210 among the optical connectors 210 may include the connector portion 220, the coupling portion 230, a main body portion 240, and a lead 250. A disposition, an arrangement, and coupling between the connector portion 220 and the edge coupler 199 may be referred to FIG. 6. FIG. 6 is a perspective view showing an optical fiber array of an example embodiment.

Referring to FIG. 1, FIG. 2, FIG. 5, and FIG. 6, the connector portion 220 may be disposed on an accommodation portion FR formed on an upper surface of the photonic integrated circuit PIC. The accommodation portion FR may have a shape recessed based on the upper surface of the photonic integrated circuit PIC. Due to the recessed shape of the accommodation portion FR, the connector portion 220 may be seated on the photonic integrated circuit PIC. In an example embodiment, the accommodation portion FR may be formed at the same level as that of the upper surface of the photonic integrated circuit PIC, and may not be recessed based on the upper surface of the photonic integrated circuit PIC. The connector portion 220 may include the optical fiber array. The optical fiber array may mean an array in which the optical fibers F are uniformly disposed (e.g., arranged at regular intervals). The optical fiber array may be disposed within the connector portion 220 by penetrating the main body portion 240. The connector portion 220 may be connected to the edge coupler 199 of the photonic integrated circuit PIC. The edge coupler 199 may be disposed within the die base 191 of the photonic integrated circuit PIC. The edge coupler 199 may include the first optical waveguides 192. The optical fiber array of the connector portion 220 may be coupled to the first optical waveguides 192 of the edge coupler 199.

The optical fiber array of the connector portion 220 may include the optical fibers F disposed in parallel with each other. The edge coupler 199 may include the first optical waveguides 192 disposed in parallel to each other. Each optical fiber F among the optical fibers F may be optically and physically coupled to a corresponding first optical waveguide among the first optical waveguides 192. The optical fiber F may have a first cross-sectional diameter, and the first optical waveguide 192 may have a second cross-sectional diameter. The first cross-sectional diameter may be equal to the second cross-sectional diameter. A cross-sectional shape of the optical fiber F may be the same as or different from a cross-sectional shape of the first optical waveguide 192. The optical fiber F may include a core O1 and a cladding layer O2. The core O1 may have a first refractive index, and the cladding layer O2 may have a second refractive index lower than the first refractive index for total reflection of the optical signal. In an example embodiment, the core O1 may be formed of or include a polymer. In an example embodiment, the cladding layer O2 may be formed of or include silicon oxide.

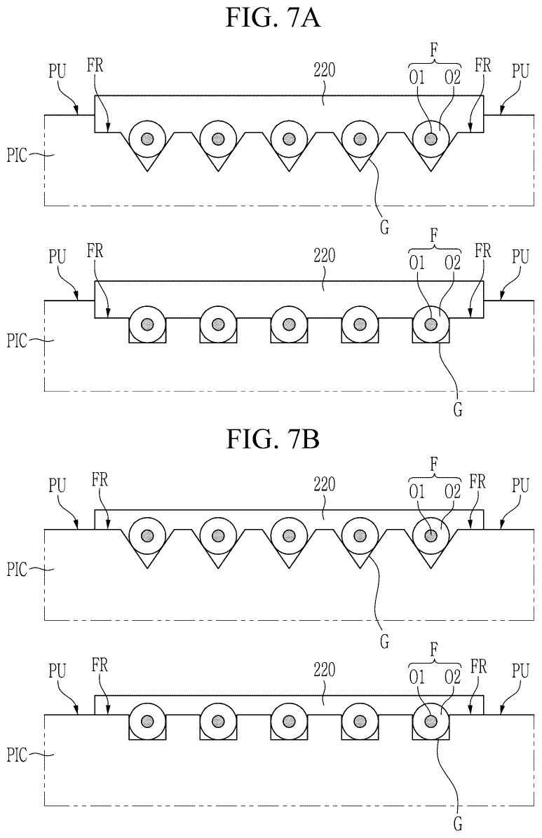

The accommodation portion FR may include grooves G on a bottom surface thereof. Each optical fiber F among the optical fibers F may be disposed within a corresponding groove G among the grooves G formed within the accommodation portion FR. A shape of the groove G may be referred to FIGS. 7A and 7B. FIGS. 7A and 7B are cross-sectional views showing the grooves G formed in the accommodation portion FR. Referring to FIG. 7A, each optical fiber F among the optical fibers F may be fixed in a position by being seated in a corresponding groove G among the grooves G formed within the accommodation portion FR having a shape recessed based on an upper surface PU of the photonic integrated circuit PIC. Referring to FIG. 7B, each optical fiber F among the optical fibers F may be fixed in a position by being seated in a corresponding groove G among the grooves G formed within the accommodation portion FR that is not recessed based on the upper surface PU of the photonic integrated circuit PIC. Referring to FIG. 6 and FIGS. 7A and 7B, on a plane, each of the grooves G may extend in a first horizontal direction. The grooves G may be disposed in parallel along a second horizontal direction intersecting the first horizontal direction. Each optical fiber F among the optical fibers F may extend along the first horizontal direction in which a corresponding groove G among the grooves G extends. The optical fibers F may be disposed in parallel along the second horizontal direction intersecting the first horizontal direction. In an example embodiment, the groove G may have a V-shape, a quadrangular shape, a circular shape, an elliptical shape, a polygonal shape, or various shapes capable of fixing or accommodating the optical fiber F.

Referring to FIG. 2 and FIG. 5, the coupling portion 230 may be inserted into the recess portion 141R formed on a side surface of the substrate 140 of the interposer GI. The coupling portion 230 may extend from the main body portion 240, and may have a shape protruding based on the main body portion 240. The coupling portion 230 may be fixed within the recess portion 141R by an adhesive member 161. The adhesive member 161 may be disposed between the recess portion 141R and the coupling portion 230, and may adhere the coupling portion 230 to the recess portion 141R. In an example embodiment, the adhesive member 161 may include an adhesive tape, an Ag paste, an epoxy resin, or polyimide. In an example embodiment, the adhesive member 161 may include a thermal interface material (TIM). In an example embodiment, the thermal interface material (TIM) may include a thermal paste, a thermal pad, a phase change material (PCM), grease, or a metal material.

The main body portion 240 may connect the connector portion 220, the coupling portion 230, and the lead 250. The lead 250 may extend from the main body portion 240, and may have a shape protruding based on the main body portion 240. The lead 250 may be disposed on the photonic integrated circuit PIC. The lead 250 may cover the connector portion 220 and the edge coupler 199. In an example embodiment, the coupling portion 230, the main body portion 240, and the lead 250 of the optical connector 210 may be formed of or include a thermoplastic resin, a thermosetting resin, or a ceramic. The coupling portion 230, the main body portion 240, and the lead 250 of the optical connector 210 may function as a heat dissipation structure that dissipates heat generated within the semiconductor package 100A to the outside, and may improve a heat dissipation characteristic of the semiconductor package 100A. If the coupling portion 230, the main body portion 240, and the lead 250 of the optical connector 210 function as the heat dissipation structure, the coupling portion 230, the main body portion 240, and the lead 250 may be formed of or may include a metal material having relatively high thermal conductivity.

According to the above example embodiments of the present disclosure, the optical connector 210 may be primarily fixed by including the coupling portion 230 inserted into the recess portion 141R formed at the substrate 140 of the interposer GI. The connector portion 220 of the optical connector 210 may be secondarily fixed by being disposed at the accommodation portion FR formed on the upper surface of the photonic integrated circuit PIC. Each of the optical fibers F within the connector portion 220 may be tertiarily fixed by being disposed in a corresponding groove among the grooves G formed within the accommodation portion FR. The connector portion 220 of the optical connector 210 may be quaternarily fixed by being covered by the lead 250. Accordingly, the optical fibers F may be precisely coupled to the first optical waveguides 192 of the edge coupler 199, and may be precisely aligned with the first optical waveguides 192 of the edge coupler 199, so that an insertion loss during a process in which the optical signal is transferred from the optical fibers F to the first optical waveguides 192 of the edge coupler 199 is reduced. Thus, signal integrity (SI) may be improved.

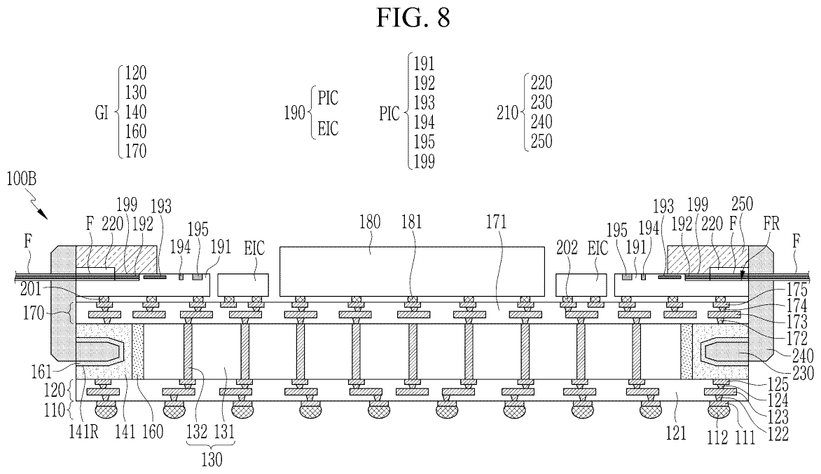

FIG. 8 is a cross-sectional view showing a semiconductor package 100B according to an example embodiment.

Referring to FIG. 8, in the semiconductor package 100B, an electronic integrated circuit EIC may be disposed to be separated from a photonic integrated circuit PIC. The electronic integrated circuit EIC may be disposed next to the photonic integrated circuit PIC. The electronic integrated circuit EIC may be disposed in parallel with the photonic integrated circuit PIC, a logic die 180, and/or a memory die 182. The electronic integrated circuit EIC may be electrically connected to the photonic integrated circuit PIC, the logic die 180, and/or the memory die 182 via an interposer GI.

The contents described for the semiconductor package 100A of FIGS. 1 to 7B may be applied to contents other than those described for the semiconductor package 100B of FIG. 8.

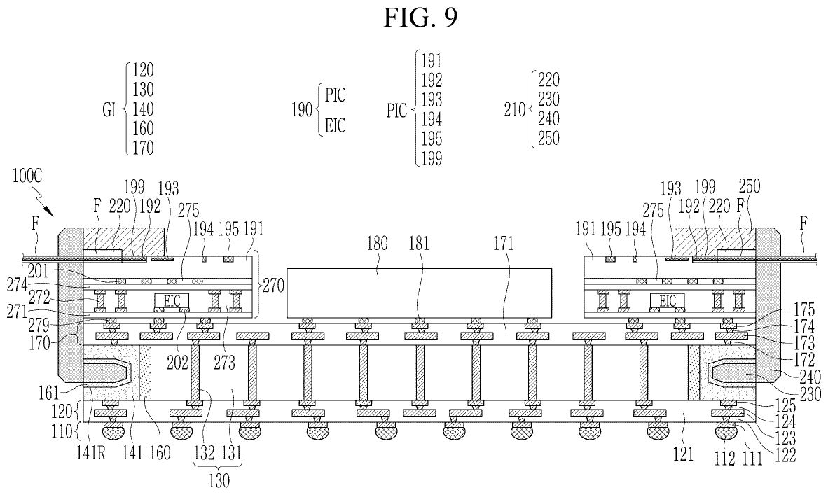

FIG. 9 is a cross-sectional view showing a semiconductor package 100C according to an example embodiment.

Referring to FIG. 9, the semiconductor package 100C may include an optical engine 190 (e.g., an optical engine package 270) formed in a package form. An electronic integrated circuit EIC may be disposed at a lower package of the optical engine package 270, and a photonic integrated circuit PIC may be disposed at an upper package of the optical engine package 270. The optical engine package 270 may include a third redistribution structure 271, the electronic integrated circuit EIC, connection members 272, a molding material 273, a fourth redistribution structure 274, an underfill material 275, and the photonic integrated circuit PIC. The optical engine package 270 may be electrically connected to an interposer GI by a solder bump 279. The third redistribution structure 271 may include redistribution lines and redistribution vias. The electronic integrated circuit EIC may be disposed above the third redistribution structure 271. The electronic integrated circuit EIC may be electrically connected to the photonic integrated circuit PIC through the third redistribution structure 271, the connection members 272, and the fourth redistribution structure 274. The connection members 272 may be disposed on the third redistribution structure 271 and next to the electronic integrated circuit EIC. The connection members 272 may include through silicon vias. The connection members 272 may electrically connect the fourth redistribution structure 274 to the third redistribution structure 271. The molding material 273 may cover the electronic integrated circuit EIC and the connection members 272 on the third redistribution structure 271. The molding material 273 may include an epoxy molding compound (EMC). The fourth redistribution structure 274 may be disposed on the molding material 273. The fourth redistribution structure 274 may include redistribution lines and redistribution vias. The photonic integrated circuit PIC may be disposed above the fourth redistribution structure 274.

The contents described for the semiconductor package 100A of FIGS. 1 to 7B may be applied to contents other than those described for the semiconductor package 100C of FIG. 9.

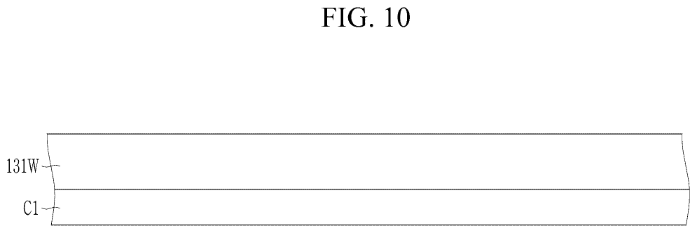

FIGS. 10 to 14 are cross-sectional views showing a method for manufacturing the glass core 130 according to an example embodiment.

FIG. 10 is a cross-sectional view showing a step of providing a glass wafer 131W on a first carrier C1.

Referring to FIG. 10, the glass wafer 131W may be provided on the first carrier C1. In an example embodiment, the first carrier C1 may include a silicon-based material such as glass or silicon oxide, another material such as an organic material or aluminum oxide, any combination thereof, or the like. In an example embodiment, the glass wafer 131W may include borosilicate glass, quartz, or non-alkali glass.

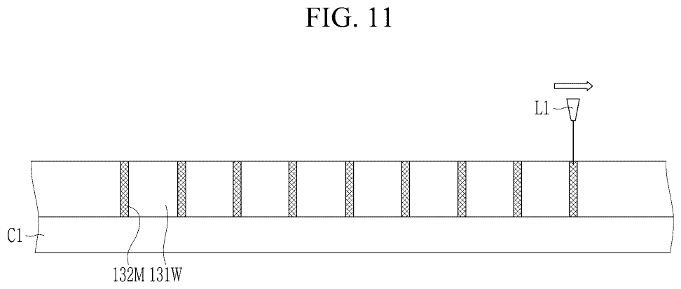

FIG. 11 is a cross-sectional view showing a step of modifying the glass wafer 131W using a laser L1.

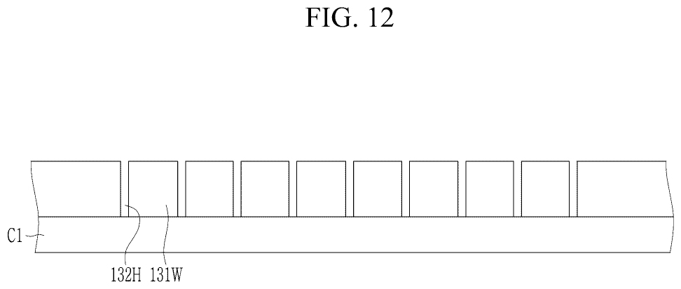

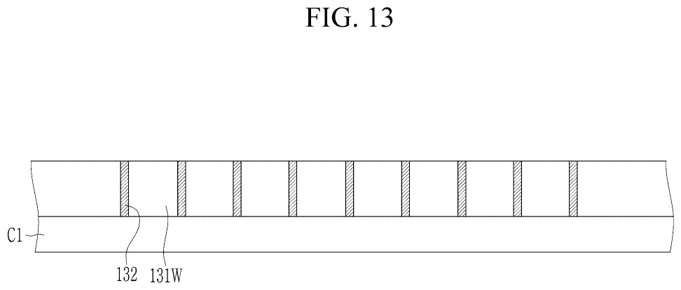

Referring to FIG. 11, the glass wafer 131W may be modified by a laser beam from the laser L1 according to a pattern of through glass vias 132 of FIG. 13 to be formed. The laser beam from the laser L1 may form a modification pattern 132M within the glass wafer 131W without destroying the glass wafer 131W. The modification pattern 132M may be a pattern for forming through holes 132H of FIG. 12. The laser beam may modify a mesh structure of the glass wafer 131W into a linear chain structure. The modification of the glass wafer 131W may be performed along a beam axis of the laser beam. The laser beam may interact with the glass wafer 131W in a form of a pulse sequence. The pulse sequence may include single pulses. In an example embodiment, the laser beam used for the modification may have a pulse width shorter than about 100 ns. In an example embodiment, the laser beam used for the modification may have a pulse width shorter than about 1 fs.

FIG. 12 is a cross-sectional view showing a step of etching the glass wafer 131W.

Referring to FIG. 12, the through holes 132H may be formed by etching the glass wafer 131W. In an example embodiment, the etching of the glass wafer 131W may be performed by isotropic wet etching. If the etching process is performed, portions of the glass wafer 131W that are not modified into the linear chain structure may hardly be etched, and the modification pattern 132M of the glass wafer 131W that is modified into a linear chain structure by the laser beam may be relatively quickly and selectively etched. Therefore, the etching may be performed along an outline of the modification pattern 132M by the laser.

FIG. 13 is a cross-sectional view showing a step of forming through the glass vias (TGVs) 132 within the glass wafer 131W.

Referring to FIG. 13, a conductive material may be filled in the through holes 132H formed in the glass wafer 131W to form the through glass vias (TGVs) 132. In an example embodiment, the through glass vias (TGVs) 132 may be formed by performing electrolytic plating or sputtering after a seed metal layer is formed. In an example embodiment, the through glass vias (TGVs) 132 may be formed by completely filling each of the through holes 132H with a conductive material. In an example embodiment, the through glass vias (TGVs) 132 may be formed by conformally forming a conductive material along each inner surface of the through holes 132H and filling the remaining space of the through holes 132H with a dielectric. In an example embodiment, the conductive material filling the interior of each of the through holes 132H may include at least one of copper, aluminum, tungsten, nickel, gold, tin, titanium, or an alloy thereof. In an example embodiment, the dielectric filling the interior of each of the through holes 132H may include a photosensitive dielectric (PID), a glass fiber implanted with a synthetic resin such as a woven glass mat (glass-epoxy) impregnated with epoxy, polyimide, FR-4, cyanate ester resin, Teflon (PTFE), polyethylene ether, or a mixture thereof.

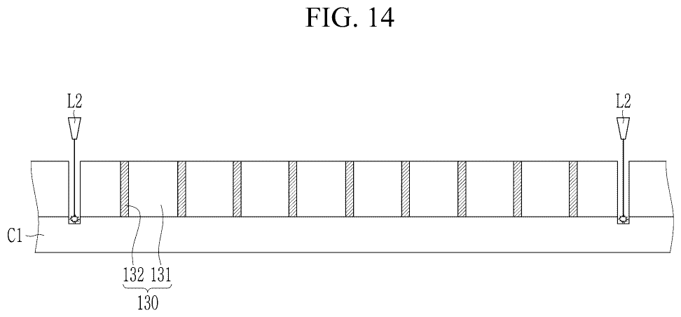

FIG. 14 is a cross-sectional view showing a step of singulating the glass wafer 131W.

Referring to FIG. 14, the glass wafer 131W may be singulated into glass cores 130. In an example embodiment, the singulation may be performed by cutting with a laser beam from a laser L2.

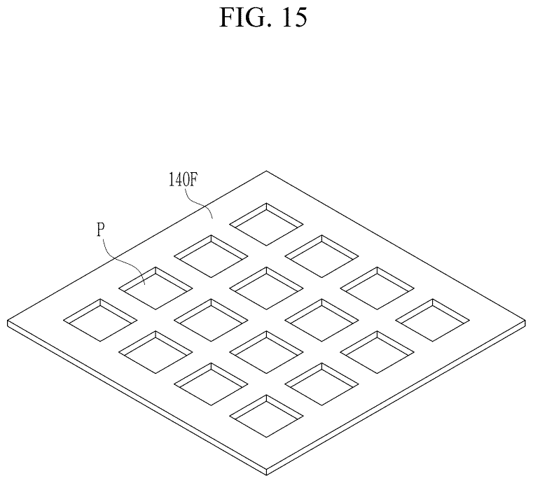

FIGS. 15 to 28 are cross-sectional views showing a method for manufacturing the semiconductor package 100A according to an example embodiment. The method for manufacturing the semiconductor package 100A according to the example embodiment of FIGS. 15 to 28 may also be applied to the method for manufacturing the semiconductor package 100B of the example embodiment of FIG. 8 and the method for manufacturing the semiconductor package 100C of the example embodiment of FIG. 9.

FIG. 15 is a view showing a step of providing a substrate frame 140F.

Referring to FIG. 15, to form the interposer GI, the substrate frame 140F formed based on the substrate 140 may be provided. The substrate frame 140F may include through openings P.

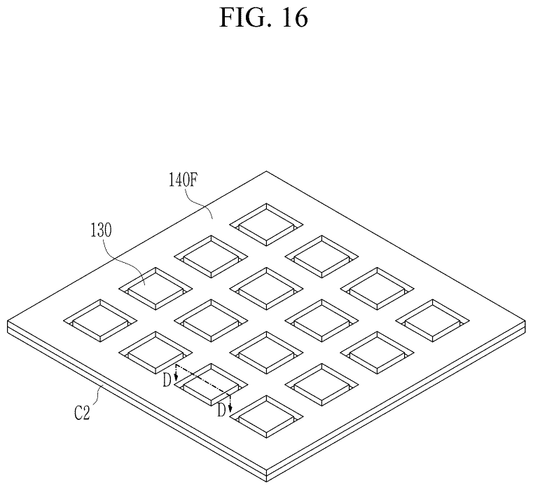

FIG. 16 is a view showing a step of disposing the glass cores 130 within the through openings P of the substrate frame 140F.

Referring to FIG. 16, a second carrier C2 may be attached below the substrate frame 140F. Thereafter, a corresponding glass core 130 among the glass cores 130 may be disposed above the second carrier C2 and within each of the through openings P of the substrate frame 140F. In an example embodiment, the second carrier C2 may include a silicon-based material such as glass or silicon oxide, another material such as an organic material or aluminum oxide, any combination thereof, or the like.

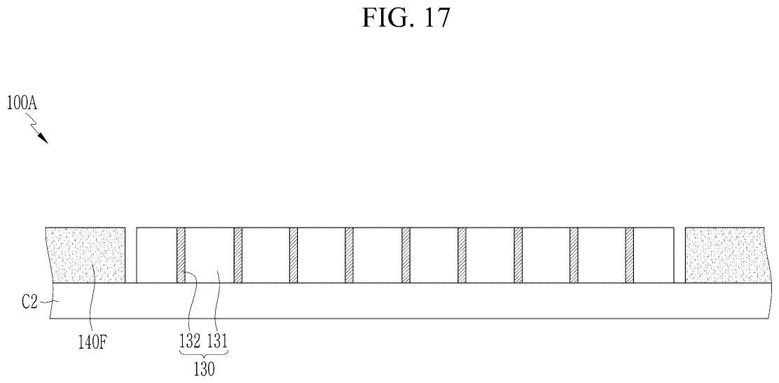

FIG. 17 is a cross-sectional view showing the substrate frame 140F of FIG. 16 cut along a line D-D.

Referring to FIG. 17, the glass cores 130 may be disposed on the second carrier C2 and within the through openings P of the substrate frame 140F.

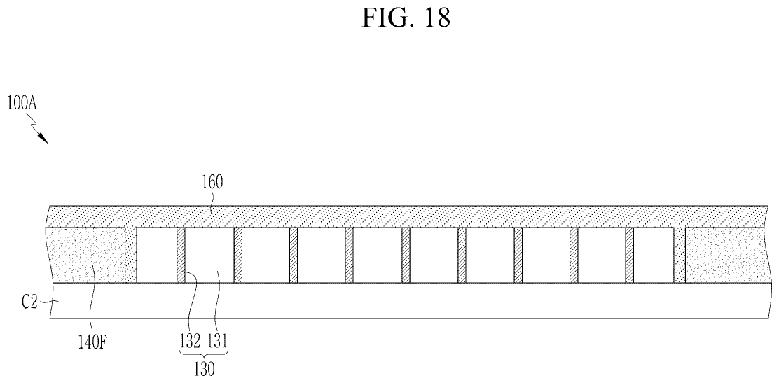

FIG. 18 is a cross-sectional view showing a step of molding the glass cores 130 with the molding material 160 on the second carrier C2 and within the substrate frame 140F.

Referring to FIG. 18, the glass cores 130 may be covered with the molding material 160 on the second carrier C2 within the substrate frame 140F. In an example embodiment, a process of molding the glass cores 130 with the molding material 160 may include a compression molding or transfer molding process. In an example embodiment, the molding material 160 may include an epoxy molding compound (EMC).

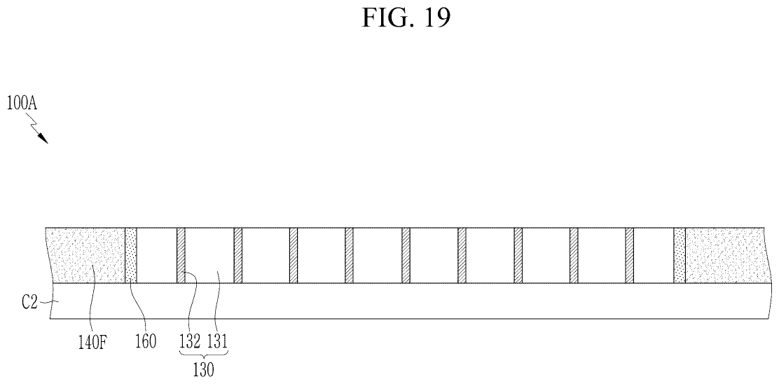

FIG. 19 is a cross-sectional view showing a step of planarizing the molding material 160.

Referring to FIG. 19, a planarization process may be performed to level an upper surface of the molding material 160. In an example embodiment, the planarization process may perform chemical mechanical polishing (CMP). After the CMP process is performed, an upper surface of the substrate frame 140F and upper surfaces of the glass cores 130 may be exposed.

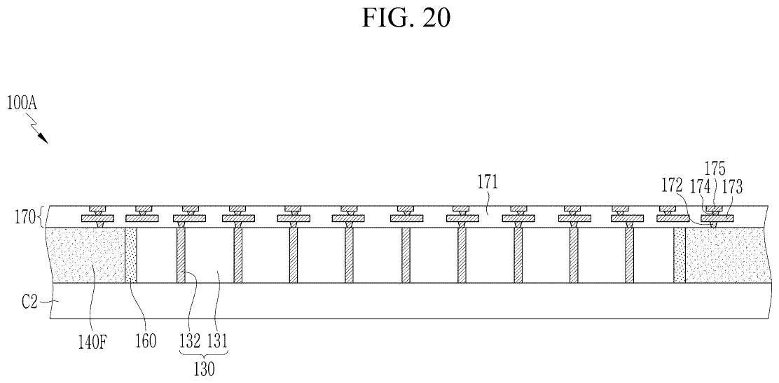

FIG. 20 is a cross-sectional view showing a step of forming the second redistribution structure 170.

Referring to FIG. 20, the second redistribution structure 170 may be formed on the upper surfaces of the glass cores 130, the upper surface of the substrate frame 140F, and the upper surface of the molding material 160. The second dielectric 171 may be formed of or include an inorganic dielectric material or an organic dielectric material. In an example embodiment, the second dielectric 171 may be formed by performing a spin coating process, a chemical vapor deposition (CVD) process, an atomic layer deposition (ALD) process, or a plasma enhanced chemical vapor deposition (PECVD) process. In an example embodiment, each of the third redistribution vias 172, the third redistribution lines 173, the fourth redistribution vias 174, and the fourth redistribution lines 175 may include at least one of copper, aluminum, tungsten, nickel, gold, tin, titanium, or an alloy thereof. In an example embodiment, each of the third redistribution vias 172, the third redistribution lines 173, the fourth redistribution vias 174, and the fourth redistribution lines 175 may be formed by performing sputtering, or may be formed by performing electrolytic plating after a seed metal layer is formed.

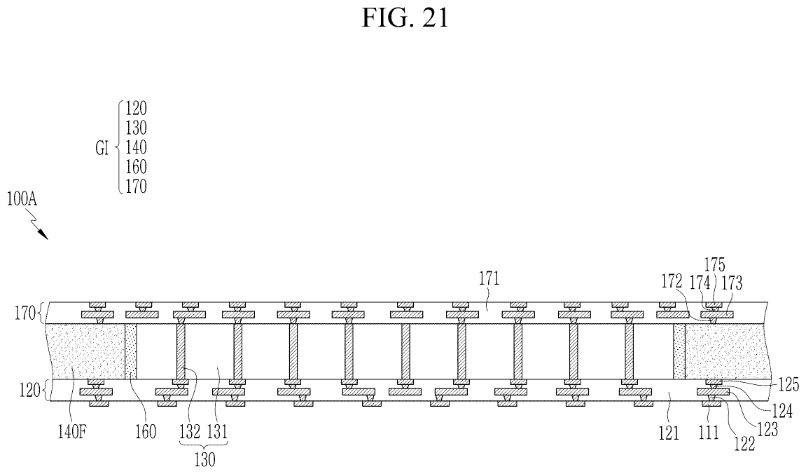

FIG. 21 is a cross-sectional view showing a step of forming the first redistribution structure 120.

Referring to FIG. 21, the second carrier C2 may be removed, and the first redistribution structure 120 may be formed below lower surfaces of the glass cores 130, a lower surface of the substrate frame 140F, and a lower surface of the molding material 160. The first dielectric 121 may be formed of or include an inorganic dielectric material or an organic dielectric material. In an example embodiment, the first dielectric 121 may be formed by performing a spin coating process, a chemical vapor deposition (CVD) process, an atomic layer deposition (ALD) process, or a plasma enhanced chemical vapor deposition (PECVD) process. In an example embodiment, each of the first redistribution vias 122, the first redistribution lines 123, the second redistribution vias 124, the second redistribution lines 125, and pillars 111 may include at least one of copper, aluminum, tungsten, nickel, gold, tin, titanium, and an alloy thereof. In an example embodiment, each of the first redistribution vias 122, the first redistribution lines 123, the second redistribution vias 124, the second redistribution lines 125, and the pillars 111 may be formed by performing sputtering, or may be formed by performing electrolytic plating after a seed metal layer is formed.

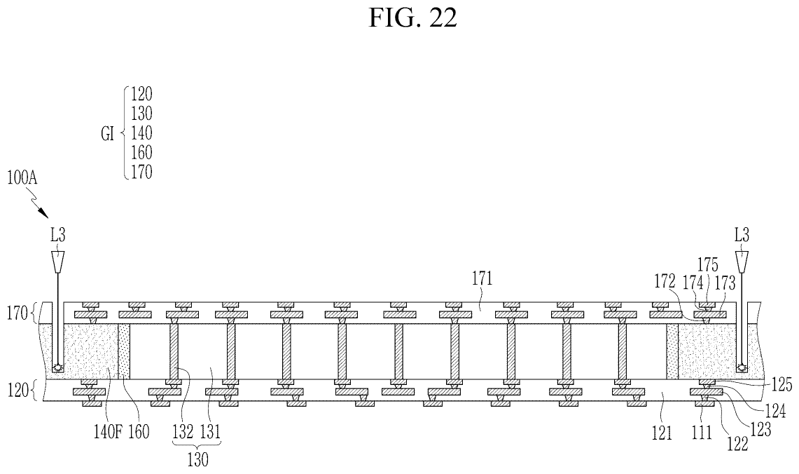

FIG. 22 is a cross-sectional view showing a step of forming the interposer GI by singulating the substrate frame 140F.

Referring to FIG. 22, the substrate frame 140F may be singulated to form the interposer GI. In an example embodiment, the individualization may be performed by cutting with a laser beam from a laser L3.

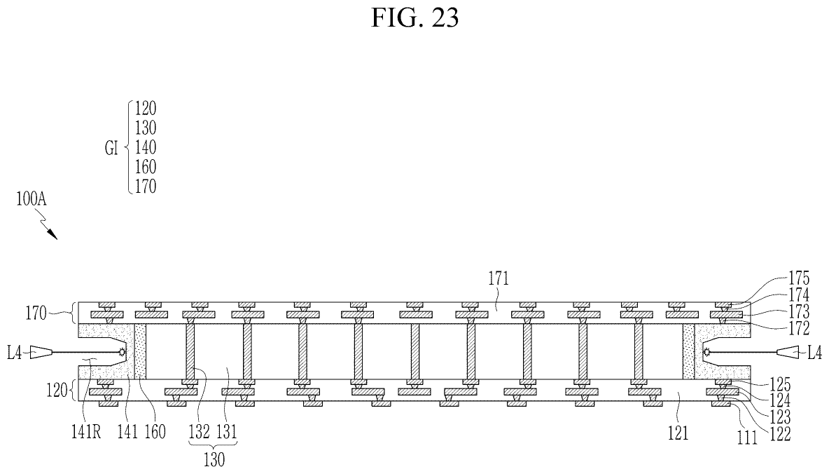

FIG. 23 is a cross-sectional view showing a step of forming the recess portions 141R on a side surface of the substrate 140 within the interposer GI.

Referring to FIG. 23, the recess portions 141R may be formed on the side surface of the substrate 140. In an example embodiment, the recess portions 141R may be performed by cutting with a laser beam from a laser L4 or mechanical drilling.

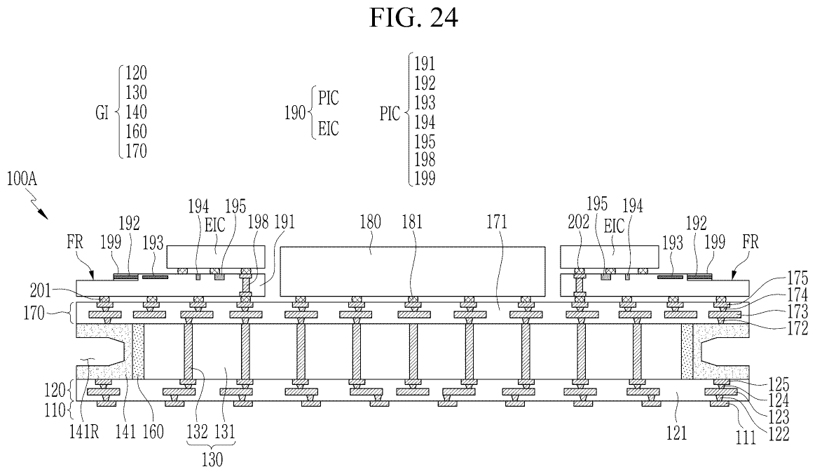

FIG. 24 is a cross-sectional view showing a step of mounting the logic die 180, the memory dies 182, and the optical engine 190 above the interposer GI.

Referring to FIG. 24, the logic die 180, the memory dies 182, and the optical engine 190 may be mounted above the interposer GI. Each of the logic die 180, the memory dies 182, and the optical engine 190 may be mounted above the interposer GI, for example, by performing a flip chip bonding process.

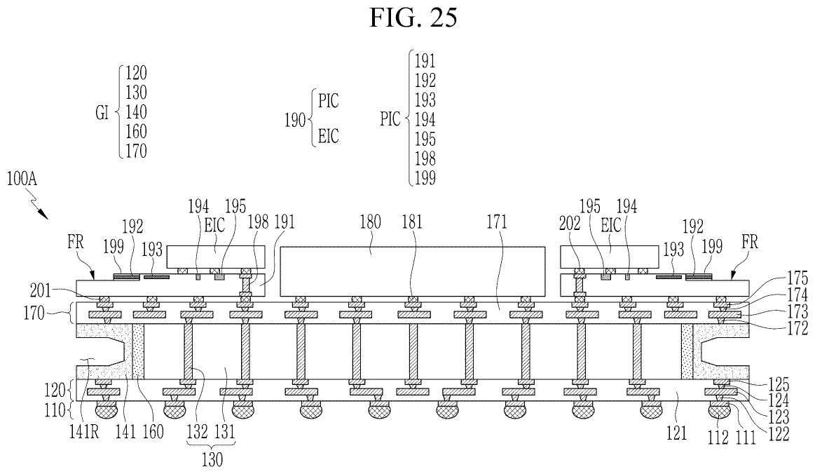

FIG. 25 is a cross-sectional view showing a step of forming solders 112 below lower surfaces of the pillars 111.

Referring to FIG. 25, the solders 112 may be formed below the lower surfaces of the pillars 111. In an example embodiment, the solders 112 may include at least one of tin, silver, lead, nickel, copper, or an alloy thereof.

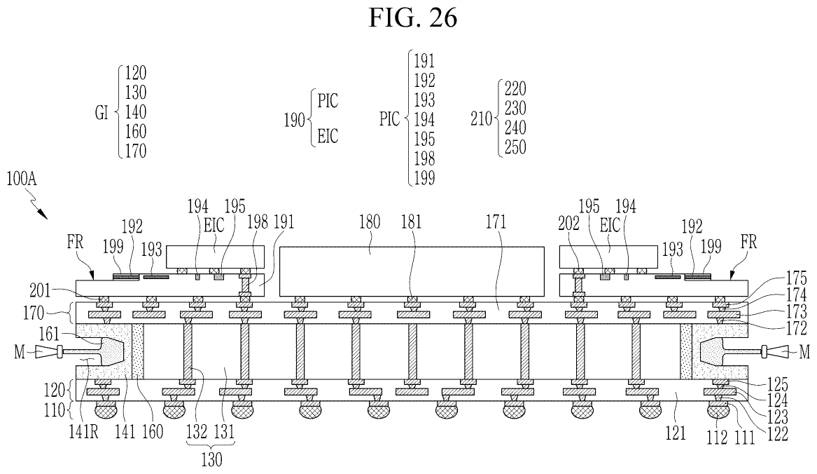

FIG. 26 is a cross-sectional view showing a step of injecting the adhesive member 161 into the interior of the recess portion 141R.

Referring to FIG. 26, the adhesive member 161 may be injected into the interior of the recess portion 141R.

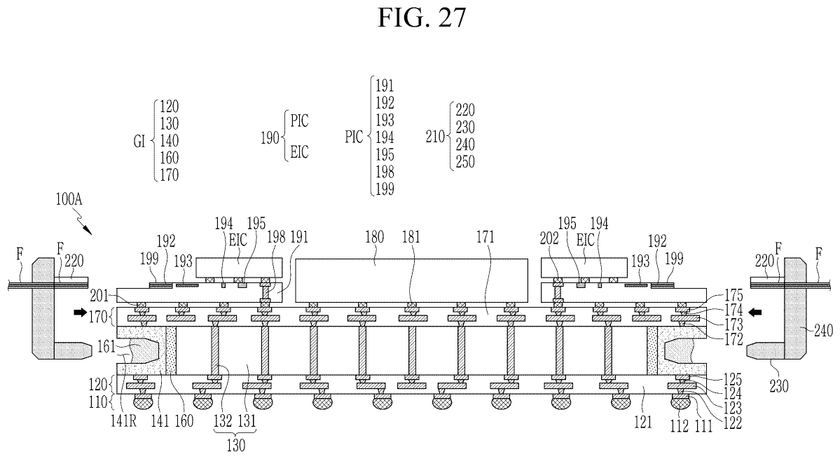

FIG. 27 is a cross-sectional view showing a step of coupling the optical connector 210 to the interposer GI and to the optical engine 190.

Referring to FIG. 27, the coupling portion 230 of the optical connector 210 may be inserted into the recess portion 141R formed at the substrate 140 within the interposer GI, and may be fixed by being adhered to the substrate 140 by the adhesive member 161. The connector portion 220 of the optical connector 210 may be coupled and fixed to the accommodation portion FR of the photonic integrated circuit PIC, and may be connected to the edge coupler 199.

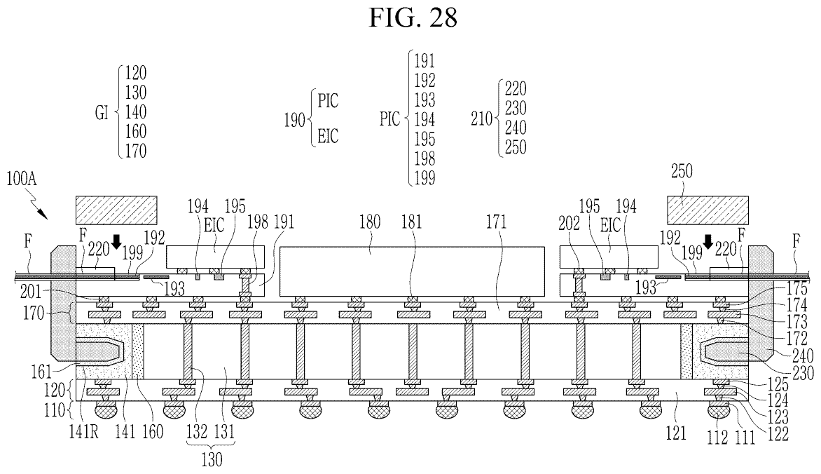

FIG. 28 is a cross-sectional view showing a step of coupling the lead 250 on the photonic integrated circuit PIC.

Referring to FIG. 28, the lead 250 may be coupled on the photonic integrated circuit PIC to cover and fix the connector portion 220 and the edge coupler 199.

While this disclosure has been described in connection with what is presently considered to be practical example embodiments, it should be understood that the disclosure is not limited to the disclosed example embodiments, but, on the contrary, is intended to cover various modifications and equivalent arrangements included within the spirit and scope of the appended claims.

What is claimed is:

1. A semiconductor package comprising:
an interposer including a glass core and a substrate around the glass core, the substrate including a recess portion on a side surface thereof;
a photonic integrated circuit (PIC) on the interposer; and
an optical connector next to the interposer,
wherein the optical connector comprises
a connector portion including a plurality of optical fibers connected to the photonic integrated circuit,
a coupling portion inserted into the recess portion, and
a main body portion connecting the connector portion to the coupling portion.

2. The semiconductor package of claim 1, wherein the photonic integrated circuit includes an accommodation portion at which the connector portion is disposed.

3. The semiconductor package of claim 2, wherein the accommodation portion is recessed based on an upper surface of the photonic integrated circuit.

4. The semiconductor package of claim 2, wherein the accommodation portion includes a plurality of grooves extending along a horizontal direction.

5. The semiconductor package of claim 4, wherein each of the plurality of optical fibers extends along the horizontal direction within a corresponding groove among the plurality of grooves.

6. The semiconductor package of claim 1, wherein the photonic integrated circuit includes an edge coupler, the edge coupler includes a plurality of optical waveguides, and each optical waveguide among the plurality of optical waveguides is connected in a line to a corresponding optical fiber among the plurality of optical fibers.

7. The semiconductor package of claim 1, further comprising:
an adhesive member between the coupling portion and the recess portion.

8. The semiconductor package of claim 1, wherein the optical connector further includes a lead covering the connector portion.

9. The semiconductor package of claim 1, wherein the coupling portion and the main body portion include a metal material.

10. A semiconductor package comprising:
an interposer including a first redistribution structure, a glass core on the first redistribution structure, a substrate on the first redistribution structure and around the glass core, a molding material on the first redistribution structure and between the glass core and the substrate, and a second redistribution structure on the glass core and the substrate, the substrate including a plurality of recess portions on a side surface thereof;
a logic die on the interposer;
a plurality of memory dies on the interposer;
a plurality of optical engines on the interposer; and
a plurality of optical connectors next to the interposer,
wherein each of the plurality of optical connectors comprises
a connector portion including an optical fiber array connected to a corresponding optical engine among the plurality of optical engines,
a coupling portion inserted into a corresponding recess portion among the plurality of recess portions, and
a main body portion connecting the connector portion to the coupling portion.

11. The semiconductor package of claim 10, wherein each of the plurality of optical engines comprises:
a photonic integrated circuit (PIC); and
an electronic integrated circuit (EIC) on the photonic integrated circuit.

12. The semiconductor package of claim 11, wherein the photonic integrated circuit includes a plurality of through silicon vias, and the plurality of through silicon vias electrically connect the electronic integrated circuit to the second redistribution structure.

13. The semiconductor package of claim 11, wherein the photonic integrated circuit includes at least one of an optical waveguide, a modulator, a photo detector, or an edge coupler.

14. The semiconductor package of claim 10, wherein each of the plurality of optical engines comprises:
a photonic integrated circuit (PIC); and
an electronic integrated circuit (EIC) next to the photonic integrated circuit.

15. The semiconductor package of claim 10, wherein each of the plurality of optical engines comprises:
a third redistribution structure;
an electronic integrated circuit (EIC) on the third redistribution structure;
a plurality of connection members on the third redistribution structure and next to the electronic integrated circuit;
a molding material covering the electronic integrated circuit and the plurality of connection members on the third redistribution structure;
a fourth redistribution structure on the molding material; and
a photonic integrated circuit (PIC) on the fourth redistribution structure.

16. The semiconductor package of claim 10, wherein the glass core includes a plurality of through glass vias, and the plurality of through glass vias electrically connect the first redistribution structure to the second redistribution structure.

17. The semiconductor package of claim 10, wherein the substrate includes a plurality of wiring layers and a plurality of vias to electrically connect the first redistribution structure to the second redistribution structure.

18. A method for manufacturing a semiconductor package, comprising:
manufacturing an interposer including a glass core and a substrate around the glass core;
forming a recess portion on a side surface of the substrate;
mounting a photonic integrated circuit (PIC) on the interposer; and
coupling an optical connector to the photonic integrated circuit and the recess portion,
wherein the optical connector comprises
a connector portion including a plurality of optical fibers connected to the photonic integrated circuit,
a coupling portion inserted into the recess portion, and
a main body portion connecting the connector portion to the coupling portion.

19. The method of claim 18, wherein the manufacturing of the interposer comprises:
forming a plurality of through glass vias within a glass wafer;
singulating the glass wafer into a plurality of glass cores;
disposing a glass core among the plurality of glass cores in a corresponding opening of the substrate including a plurality of openings;
molding the plurality of glass cores with a molding material;
forming an upper redistribution structure on upper surfaces of the plurality of glass cores and an upper surface of the substrate;
forming a lower redistribution structure on lower surfaces of the plurality of glass cores and a lower surface of the substrate; and
singulating the substrate into individual units.

20. The method of claim 19, wherein the forming of the plurality of through glass vias comprises:
modifying the glass wafer with a laser according to a pattern of the plurality of through glass vias to be formed;
performing etching on the glass wafer to form a plurality of through holes; and
filling a conductive material into the plurality of through holes.
